(19) United States
(12) Patent Application Publication
(10) Pub. No.: US 2018/0366610 A1
(43) Pub. Date: Dec. 20, 2018

(54) APPARATUS FOR CUTTING SOLAR PANEL

(71) Applicant: DMS CO., LTD., Yongin-si (KR)

(72) Inventors: Yong Seok PARK, Seoul (KR); Gyoo Won SEO, Hwaseong-si (KR); Hee Won KIM, Seoul (KR); Min Shik KIM, Seoul (KR); Yun Kwang CHOI, Yongin-si (KR)

(73) Assignee: DMS CO., LTD., Yongin-si (KR)

(21) Appl. No.: 15/728,510

(22) Filed: Oct. 10, 2017

(30) Foreign Application Priority Data
Jun. 14, 2017 (KR) 10-2017-0074652

(51) Int. Cl. H01L 31/18; B26F 3/00

(52) U.S. Cl. CPC H01L 31/1876; H01L 31/042; B26F 3/002

(57) ABSTRACT

Disclosed is an apparatus for cutting a solar panel, which includes a power generating section which generates power; a base section provided which is placed under the solar panel, a negative-pressure generating section which is placed under the stationary plate and the respective rotary plates, a power splitting section which receives the power from the power generating section and splits the power into rotary power in different directions; and a power transmitting section which divisionally transmits the rotary power in different directions to the first rotary section and the second rotary section.

### CROSS-REFERENCE TO RELATED APPLICATION

This application claims priority from Korean Patent Application No. 10-2017-0074652, filed on Jun. 14, 2017 in the Korean Intellectual Property Office, the disclosure of which is incorporated herein by reference.

### BACKGROUND OF THE INVENTION

### (a) Field of the Invention

The present invention relates to an apparatus for cutting a solar panel, and more particularly to an apparatus for cutting a solar panel, which gets multiple solar panels simultaneously to thereby improve productivity.

### (b) Description of the Related Art

In general, solar photovoltaic power generation refers to a power generation scheme that directly converts sunlight into electricity through a solar cell. The solar photovoltaic power generation has advantages that there is no need to worry about air pollution, noise, heat generation, vibration, etc.; there is no need to transport a fuel; less cost and effort are required for maintenance of power equipment; the power equipment has a long life; and it is easy to select a scale of equipment and install the equipment.

The solar photovoltaic power generation is achieved in the solar cell. The efficiency of the solar cell is varied depending on how efficiently a silicon wafer surface absorbs incident light. A collection of solar cells is called a solar battery, and the solar battery made into a panel is called a solar panel.

To improve the efficiency of the solar photovoltaic power generation, a plurality of solar panels is installed to be used as a solar module. In general, the solar module is manufactured by mounting the solar panels to a base plate and electrically connecting the respective solar panels.

FIG. 1 is a view for explaining a conventional singulation process for a solar panel.

As shown in (a) of FIG. 1, a cutting line 20 is formed on an original solar panel 10 by a laser in accordance with desired sizes of the solar panel 10 in the singulation process for cutting the solar panel among the processes of manufacturing the solar module. Further, as shown in (b) of FIG. 1, the solar panel 10 is placed with the cutting line 20 facing down between projections 31 on a work table 30, and then the original solar panel 10 is pressed to be cut at the cutting line 20 by a pressing member 40. Thus, it is possible to get a solar panel 11 having a desired size.

However, the foregoing method has problems of increasing time taken in the cutting process and decreasing productivity, since the pressing member 40 cuts one cutting line 20 at a time.

### SUMMARY OF THE INVENTION

Accordingly, the present invention is conceived to solve the conventional problems, and an aspect of the present invention is to provide an apparatus for cutting a solar panel, which gets multiple solar panels simultaneously to thereby improve productivity.

According to an aspect of the present invention, there is provided an apparatus for cutting a solar panel, comprising: a power generating section which generates power; a base section which comprises a stationary plate, a first rotary section comprising a plurality of rotary plates rotatably coupled to one side of the stationary plate, a second rotary section comprising a plurality of rotary plates rotatably coupled to the other side of the stationary plate, and puts the solar panel thereon; a negative-pressure generating section which is placed under the stationary plate and the respective rotary plates, and generates negative pressure in between the solar panel and top surfaces of the stationary plate and the plurality of rotary plates so that the solar panel can be attached to the stationary plate and the plurality of rotary plates; a power splitting section which receives the power from the power generating section and splits the power into rotary power in different directions; and a power transmitting section which divisionally transmits the rotary power in different directions to the first rotary section and the second rotary section so that the solar panel can be bent and cut as the respective rotary plates are symmetrically rolled upward with respect to the stationary plate.

### BRIEF DESCRIPTION OF THE DRAWINGS

The above and/or other aspects of the present invention will become apparent and more readily appreciated from the following description of the exemplary embodiments, taken in conjunction with the accompanying drawings, in which:

FIG. 1 is a view for explaining a conventional singulation process for a solar panel;

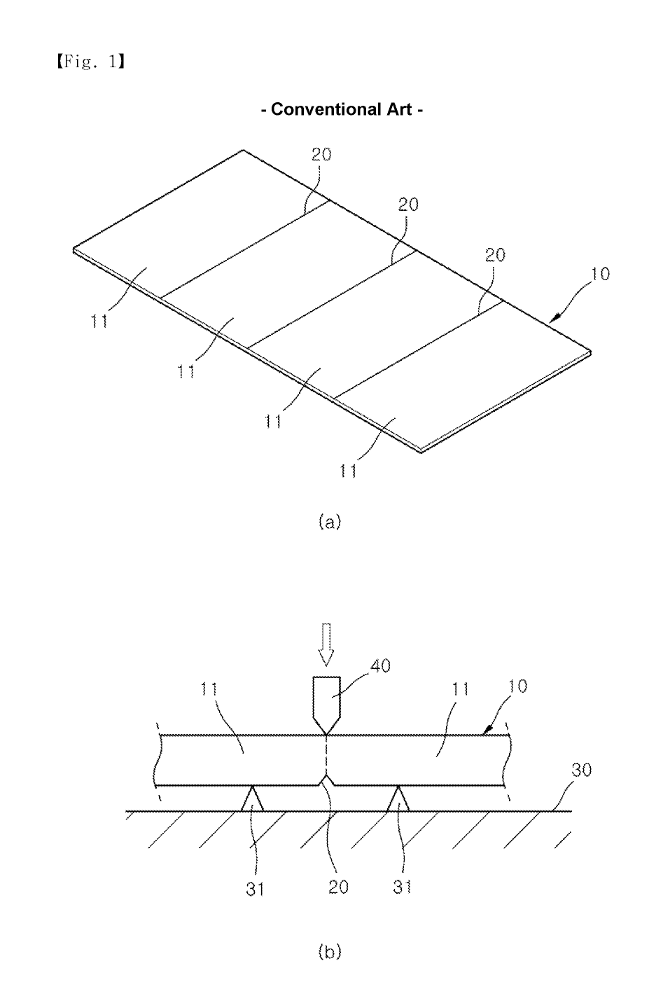

FIG. 2 and FIG. 3 are perspective views of an apparatus for cutting a solar panel according to an embodiment of the present invention;

FIG. 4 is a perspective view of mainly showing a power splitting section in the apparatus for cutting the solar panel according to an embodiment of the present invention;

FIG. 5 is a perspective view of mainly showing a power transmitting section in the apparatus for cutting the solar panel according to an embodiment of the present invention;

FIG. 6 is a perspective view of mainly showing a base section in the apparatus for cutting the solar panel according to an embodiment of the present invention;

FIG. 7 is an exploded perspective view of FIG. 6;

FIG. 8 is a cross-sectional view taken along line A-A of FIG. 6;

FIG. 9 is a cross-sectional view taken along line B-B of FIG. 6; and

FIG. 10 is a view of showing operations of the apparatus for cutting the solar panel according to an embodiment of the present invention.

### DETAILED DESCRIPTION OF THE EMBODIMENTS

Hereinafter, embodiments of an apparatus for cutting a solar panel according to the present invention will be described with reference to the accompanying drawings. The present invention is not limited or restricted by the following embodiments. Further, detailed descriptions of publicly known functions or structures may be omitted to make the gist of the present invention clear.

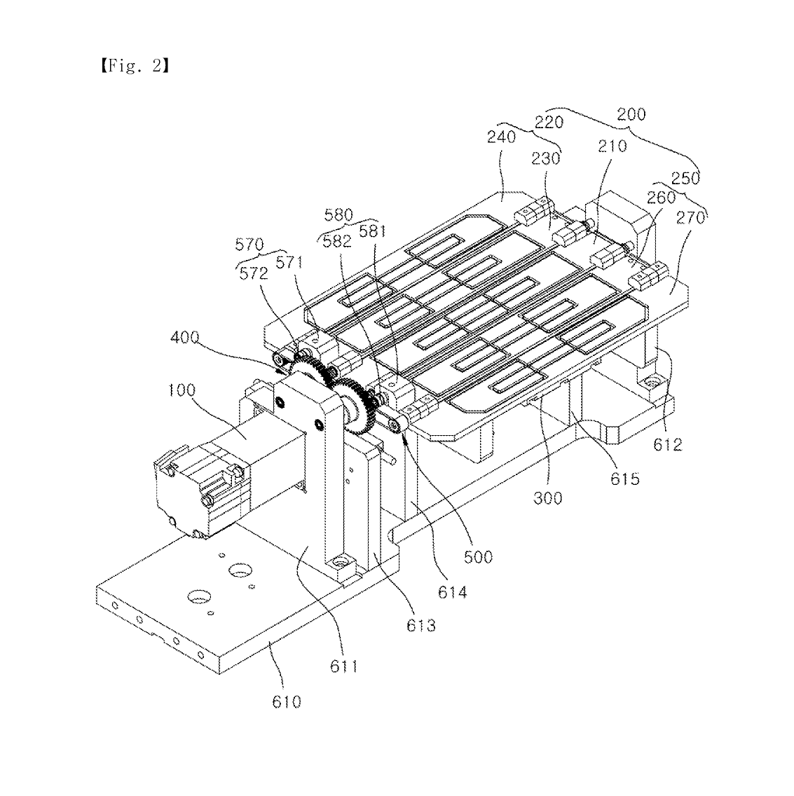

FIG. 2 and FIG. 3 are perspective views of an apparatus for cutting a solar panel according to an embodiment of the present invention;

As shown in FIG. 2 and FIG. 3, the apparatus for cutting the solar panel may include a power generating section 100, a base section 200, a negative-pressure generating section 300, a power splitting section 400 and a power transmitting section 500.

Further, the apparatus for cutting the solar panel may include a base frame 610, a first mount 611, a second mount 612, a vertical frame 613, a first support frame 614 and a second support frame 615.

The base frame 610 may be arranged in a horizontal direction, and the first mount 611 and the second mount 612 may be provided on the base frame 610 and spaced apart from each other. Further, the vertical frame 613 may be in close contact with the first mount 611.

The power generating section 100 may be provided to pass through the first mount 611 and the vertical frame 613 and generate rotary power.

The base section 200 may include a stationary plate 210, a first rotary section 220 and a second rotary section 250. The first rotary section 220 may be placed at one side of the stationary plate 210, and include a first rotary plate 230 and a second rotary plate 240 which are coupled to be rotated with respect to each other. The second rotary section 250 may be placed at the other side of the stationary plate 210, and include a third rotary plate 260 and a fourth rotary plate 270 which are coupled to be rotated with respect to each other. Thus, the solar panel may be put on the base section 200. The base section 200 may be arranged in between the first mount 611 and the second mount 612.

The first support frame 614 and the second support frame 615 may be provided in between the first mount 611 and the second mount 612. The upper portions of the first support frame 614 and the second support frame 615 are formed to have widths corresponding to the width of the base section 200, and thus support the stationary plate 210 and the respective rotary plates 230, 240, 260 and 270 in the state that the respective rotary plates 230, 240, 260 and 270 of the first support frame 614 and the second support frame 615 are spread out horizontally.

The negative-pressure generating section 300 may be provided under the stationary plate 210 and the respective rotary plates 230, 240, 260 and 270. The negative-pressure generating section 300 may provide negative pressure between the solar panel 10 and the upper portions of the stationary plate 210 and the respective rotary plates 230, 240, 260 and 270, thereby holding the solar panel 10 on the base section 200.

The power splitting section 400 receives power generated in the power generating section 100 and splits it into rotary power for different rotating directions.

The power transmitting section 500 makes the rotary power for different rotating directions, split by the power splitting section 400, be simultaneously provided to the first rotary section 220 and the second rotary section 250 of the base section 200, respectively. Thus, the first rotary section 220 and the second rotary section 250 may be upward rolled symmetrically or spread out with respect to the stationary plate 210.

The cutting lines 20 are formed on the original solar panel 10 at intervals corresponding to the widths of the stationary plate 210 and the rotary plates 230, 240, 260 and 270. In the state that the original solar panel 10 is put with the cutting lines 20 facing down on the base section 200, and held on the base section 200 by negative pressure generated by the negative-pressure generating section 300, if the respective rotary plates 230, 240, 260 and 270 are rolled upward, the original solar panel 10 is bent and cut with respect to the cutting line 20. Thus, it is possible to simultaneously get a plurality of solar panels cut to have a desired small size from the original solar panels, thereby improving productivity.

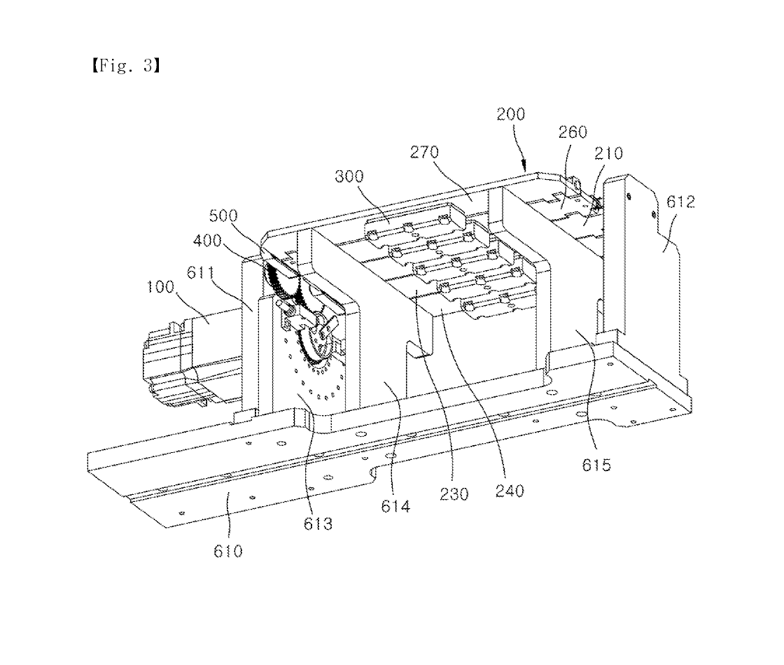

FIG. 4 is a perspective view of mainly showing a power splitting section in the apparatus for cutting the solar panel according to an embodiment of the present invention.

As shown in FIG. 2 to FIG. 4, the power splitting section 400 may include a main gear 410, a first split gear 420 and a second split gear 430.

The main gear 410 may be rotated by power transmitted from the power transmitting section 500. The main gear 410 may be connected to a main shaft 110 of the power transmitting section 500. Further, the main gear 410 may be placed inside an installation groove 616 formed in the vertical frame 613. The main gear 410 may couple with a counter bar 411, and the vertical frame 613 may include sensors 412 at opposite sides of the main gear 410. The sensors 412 may sense the counter bar 411, and thus determine a rotation amount including the number of rotations of the main gear 410. The rotation amount may be taken into account as data for controlling the rotation amount and rotating directions of the main gear 410.

A first driving shaft 440 may be coupled to the center of the first split gear 420, and the first driving shaft 440 may be rotatably coupled to the first mount 611. The first split gear 420 is placed above the main gear 410 and engages with the main gear 410, thereby rotating in a counter direction to the rotating direction of the main gear 410. The first driving shaft 440 may have a first stepped portion 441 flat on a circumferential surface thereof.

A second driving shaft 450 may be coupled to the center of the second split gear 430, and the second driving shaft 450 may be rotatably coupled to the first mount 611. The second driving shaft 450 may be placed at the same height as the first driving shaft 440. The second driving shaft 450 may have a second stepped portion 451 flat on a circumferential surface thereof.

The second split gear 430 may be formed corresponding to the first split gear 420, and engage with the first split gear 420. Thus, the second split gear 430 may rotate in the counter direction to the rotating direction of the first split gear 420. That is, when the main gear 410 rotates, the first split gear 420 and the second split gear 430 are simultaneously rotated in the counter directions to each other. The first split gear 420 and the second split gear 430 may have the same shape and rotate by the same rotation amount.

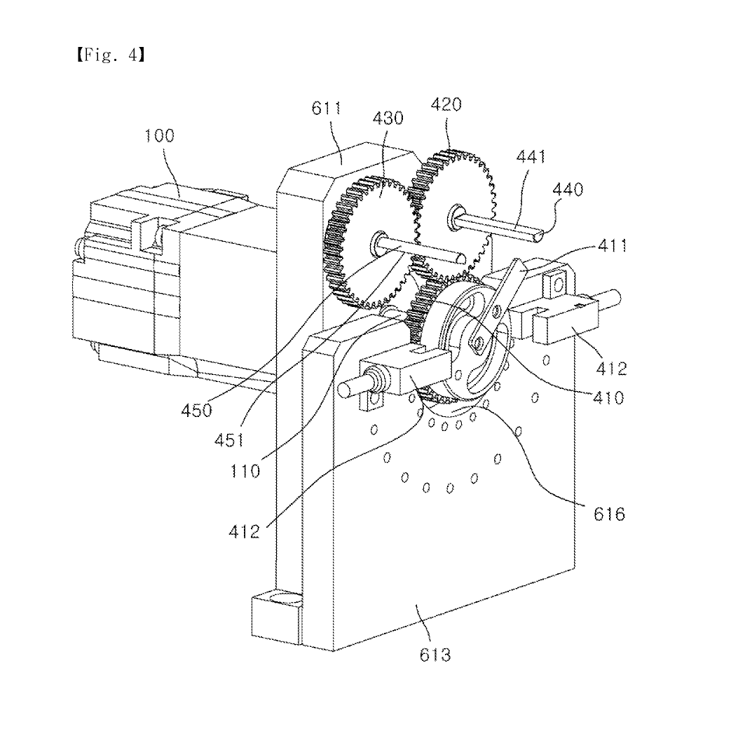

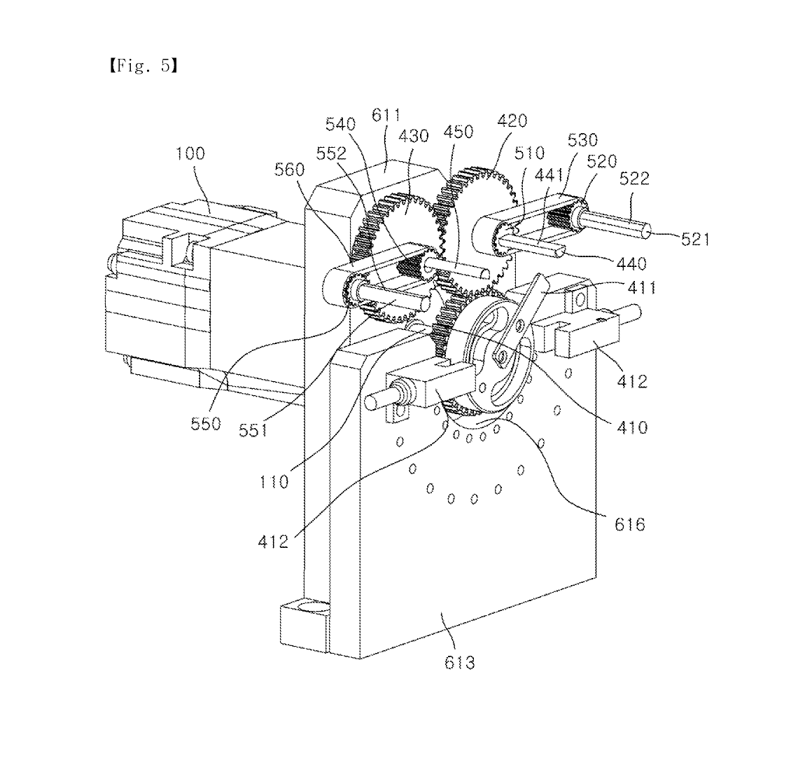

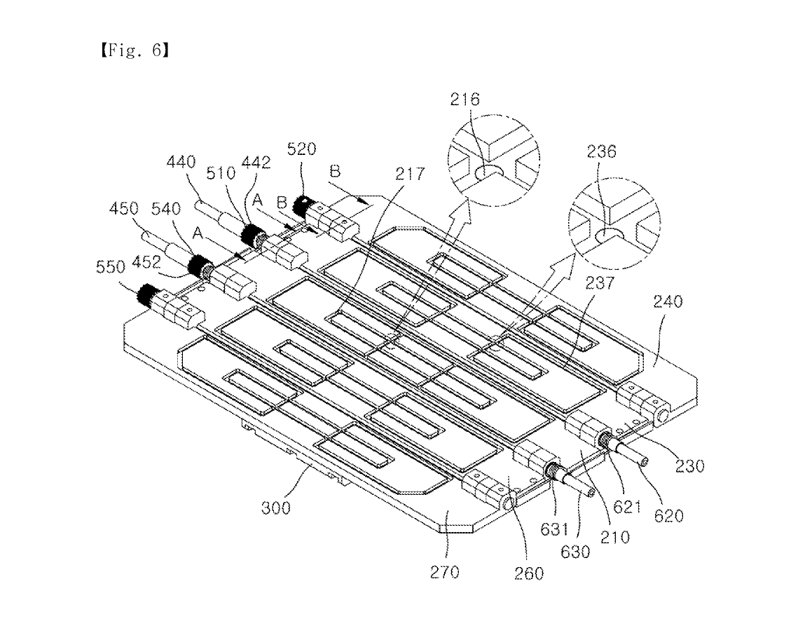

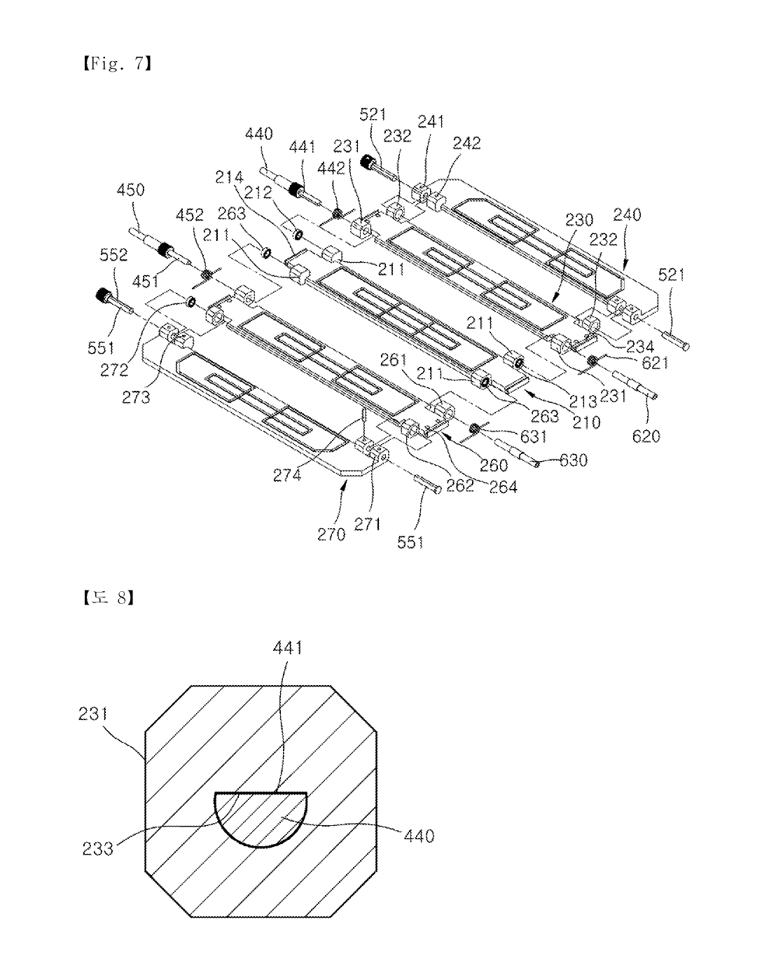

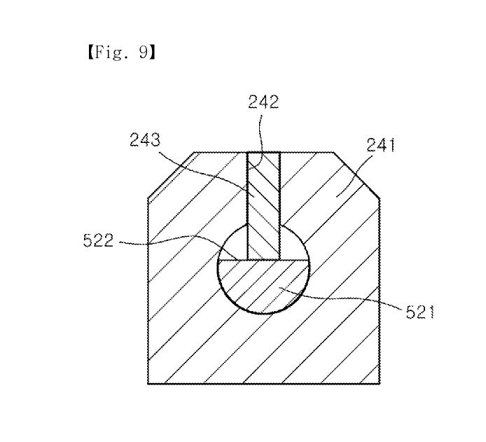

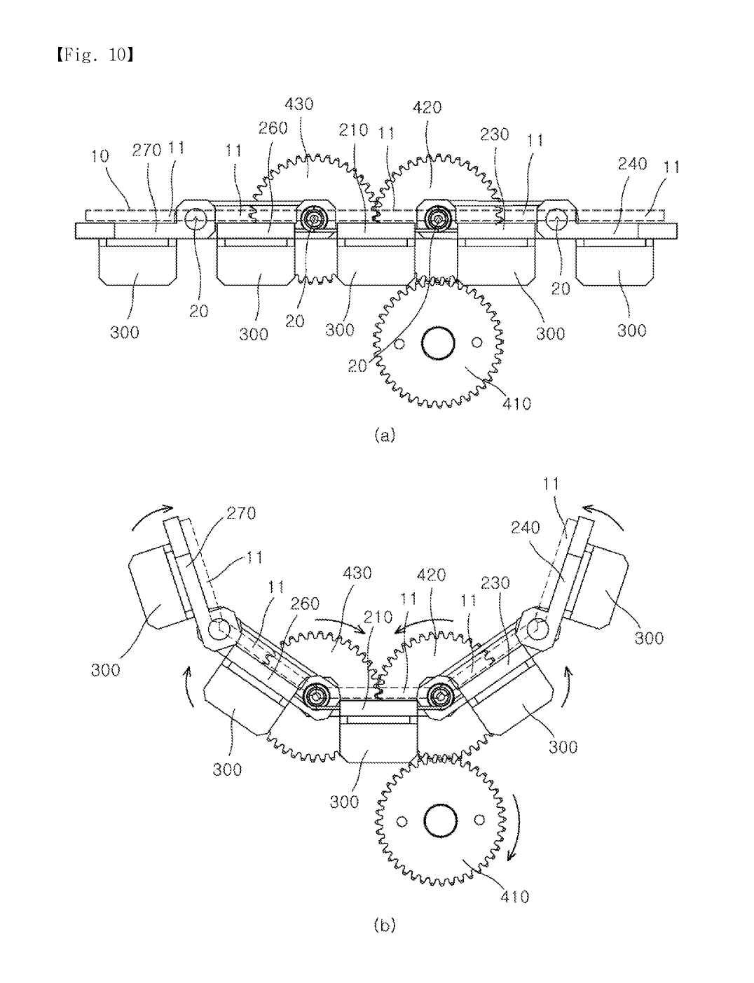

FIG. 5 is a perspective view of mainly showing a power transmitting section in the apparatus for cutting the solar panel according to an embodiment of the present invention, FIG. 6 is a perspective view of mainly showing a base section in the apparatus for cutting the solar panel according to an embodiment of the present invention, FIG. 7 is an exploded perspective view of FIG. 6, FIG. 8 is a cross-sectional view taken along line A-A of FIG. 6, FIG. 9 is a cross-sectional view taken along line B-B of FIG. 6, and FIG. 10 is a view of showing operations of the apparatus for cutting the solar panel according to an embodiment of the present invention. Below, FIG. 5 to FIG. 10 will be additionally referred to in the following descriptions.

As shown in FIG. 2 to FIG. 10, the stationary plate 210 may have a pair of first hinges 211 at opposite end portions thereof.

Likewise, the first rotary plate 230 may have a second hinge 231 at one side of opposite end portions thereof, and a third hinge 232 at the other side of the opposite end portions. Among them, the second hinge 231 formed at a first end portion of the first rotary plate 230 may couple with the first hinge 211 formed at one side of the first end portion of the stationary plate 210 by the first driving shaft 440. The first driving shaft 440 and the first hinge 211 may be coupled through a bearing 212, and thus the first driving shaft 440 may be rotated independently of the first hinge 211. That is, the first driving shaft 440 is rotatable even though the stationary plate 210 is not rotatable but stationary.

Further, a first coupling groove 233 shaped corresponding to the first stepped portion 441 formed in the first driving shaft 440 may be formed on an inner circumferential surface of the second hinge 231 to which the first driving shaft 440 is coupled. When the first driving shaft 440 is inserted in and coupled to the second hinge 231, the first stepped portion 441 engages with the first coupling groove 233, and thus the rotary power of the first driving shaft 440 is transmitted to the second hinge 231 when the first driving shaft 440 rotates, thereby rotating the second hinge 231. That is, when the first driving shaft 440 rotates, the first rotary plate 230 rotates together with the first driving shaft 440. Thus, the first rotary plate 230 is coupled to one side of the stationary plate 210 and independently rotatable even though the stationary plate 210 is stationary.

Further, the second hinge 231 formed at the second end portion of the first rotary plate 230 may couple with the first hinge 211 formed at the second end portion of the one side of the stationary plate 210 by a first locking shaft 620 coupled to the second mount 612. The first locking shaft 620 may couple with the first hinge 211 by a bearing 213, and may also couple with the second hinge 231 by the bearing (not shown). Thus, the first hinge 211 and the second hinge 231 may rotate independently of each other with respect to the first locking shaft 620.

In addition, the second rotary plate 240 may have a fourth hinge 241 at one side of the opposite end portions, and the fourth hinge 241 may axially couple with the third hinge 232 of the first rotary plate 230 by a first driven shaft 521. The first driven shaft 521 may couple with the third hinge 232 by the bearing (not shown), and be rotatable independently of the third hinge 232. That is, the second rotary plate 240 is rotatable independently of the first rotary plate 230.

Further, the fourth hinge 241 may be formed with a first locking hole 242, and the first driven shaft 521 may be formed with a third stepped portion 522. Further, the first locking hole 242 may be couple with a first locking pin 243, and the first locking pin 243 may press the third stepped portion 522. Therefore, when the first driven shaft 521 rotates, the rotary power of the first driven shaft 521 is transmitted to the fourth hinge 241 through the first locking pin 243 so that the second rotary plate 240 can rotate together with the first driven shaft 521. Thus, the second rotary plate 240 may be provided at the other side of the first rotary plate 230 and rotatable independently of the first rotary plate 230.

In addition, the third rotary plate 260 may have a fifth hinge 261 at one side of the opposite end portions, and have a sixth hinge 262 at the other side of the opposite end portions. Between them, the fifth hinge 261 formed at the first end portion of the third rotary plate 260 may couple with the first hinge 211 formed at the other side of the first end portion of the stationary plate 210 by the second driving shaft 450. The second driving shaft 450 and the first hinge 211 may be coupled by a bearing 263, and thus the second driving shaft 450 can rotate independently of the first hinge 211. That is, the second driving shaft 450 is rotatable even though the stationary plate 210 is stationary so as not to be rotated.

Further, the inner circumferential surface of the fifth hinge 261 coupling with the second driving shaft 450 may be formed with the second coupling groove (not shown) shaped corresponding to the second stepped portion 451 formed in the second driving shaft 450. When the second driving shaft 450 is inserted in and couples with the fifth hinge 261, the second stepped portion 451 may be inserted in and engages with the second coupling groove and thus the rotary power of the second driving shaft 450 can be transmitted to the fifth hinge 261. That is, when the second driving shaft 450 rotates, the third rotary plate 260 rotates together with the second driving shaft 450. Thus, the third rotary plate 260 is coupled to the other side of the stationary plate 210 and is rotatable even though the stationary plate 210 is stationary.

Further, the fifth hinge 261 formed in the second end portion of the third rotary plate 260 may couple with the first hinge 211 formed in the other second end portion of the stationary plate 210 by a second locking shaft 630 coupled to the second mount 612. The second locking shaft 630 may couple with the first hinge 211 by the bearing 263, and couple with the fifth hinge 261 by the bearing (not shown). Thus, the first hinge 211 and the fifth hinge 261 may rotate independently of each other with respect to the second locking shaft 630.

Further, the fourth rotary plate 270 may have a seventh hinge 271 at one side of the opposite end portions, and the seventh hinge 271 may axially couple with the sixth hinge 262 of the third rotary plate 260 by a second driven shaft 551. The second driven shaft 551 couples with the sixth hinge 262 by a bearing 272 and is rotatable independently of the sixth hinge 262. That is, the fourth rotary plate 270 may rotate independently of the third rotary plate 260.

Further, the seventh hinge 271 may be formed with a second locking hole 273, and the second driven shaft 551 may be formed with a fourth stepped portion 552. Further, the second locking hole 273 may couple with a second locking pin 274, and the second locking pin 274 may press the fourth stepped portion 552. Therefore, when the second driven shaft 551 rotates, the fourth rotary plate 270 rotates together with the second driven shaft 551, and thus the fourth rotary plate 270 is provided at the other side of the third rotary plate 260 and rotatable independently of the third rotary plate 260.

Further, first settling grooves 214 may be formed on a top surface of the stationary plate 210 at the opposite end portions, respectively. The first settling groove 214 may be formed in a widthwise direction of the stationary plate 210. Likewise, second settling grooves 234 may be respectively formed on a top surface of the first rotary plate 230 at the opposite end portions, respectively. The second settling groove 234 may be formed in a widthwise direction of the first rotary plate 230, and communicate with the first settling groove 214. Further, third settling grooves 264 may be formed on a top surface of the third rotary plate 260 at the opposite end portions, respectively. The third settling groove 264 may be formed in a widthwise direction of the third rotary plate 260, and communicate with the first settling groove 214.

In addition, the first driving shaft 440 may be provided with a first elastic member 442. The first elastic member 442 has opposite end portions to be respectively settled in the first settling groove 214 formed at the first end portion of the stationary plate 210 and the second settling groove 234 formed at the first end portion of the first rotary plate 230. The first elastic member 442 may elastically urge the first rotary plate 230 to rotate in a spreading-out direction with respect to the stationary plate 210.

Further, the second driving shaft 450 may be provided with a second elastic member 452. The second elastic member 452 has opposite end portions to be respectively settled in the first settling groove 214 formed at the first end portion of the stationary plate 210 and the third settling groove 264 formed at the first end portion of the third rotary plate 260. The second elastic member 452 may elastically urge the third rotary plate 260 to rotate in a spreading-out direction with respect to the stationary plate 210.

Likewise, the first locking shaft 620 may be provided with a third elastic member 621. The third elastic member 621 has opposite end portions to be respectively settled in the first settling groove 214 formed at the second end portion of the stationary plate 210 and the second settling groove 234 formed at the second end portion of the first rotary plate 230. The third elastic member 621 may elastically urge the first rotary plate 230 to rotate in a spreading-out direction with respect to the stationary plate 210.

Further, the second driving shaft 450 may be provide with a fourth elastic member 631. The fourth elastic member 631 has opposite end portions to be respectively settled in the first settling groove 214 formed at the second end portion of the stationary plate 210 and the third settling groove 264 formed at the second end portion of the third rotary plate 260. The fourth elastic member 631 may elastically urge the third rotary plate 260 to rotate in a spreading-out direction with respect to the stationary plate 210.

Further, the stationary plate 210 may include a first through hole 216 and a first groove 217.

The first through hole 216 may be formed to penetrate the stationary plate 210 in a thickness direction, and communicate with the negative-pressure generating section 300. The first groove 217 may be formed on the top surface of the stationary plate 210, and communicate with the first through hole 216. Thus, negative pressure generated in the negative-pressure generating section 300 may be supplied to the first groove 217 via the first through hole 216, so that the original solar panel and the cut solar panel can be attached to the stationary plate 210. To more effectively apply the negative pressure between the stationary plate 210 and the solar panel, the first groove 217 may be widespread on the stationary plate 210, and the number and positions of first through holes 216 may be adjusted.

Further, each of the rotary plates 230, 240, 260 and 270 may have a second through hole 236 and a second groove 237.

The second through hole 236 may be formed to penetrate each of the rotary plates 230, 240, 260 and 270 in a thickness direction, and communicate with the negative-pressure generating section 300. The second groove 237 may be formed on each top surface of the rotary plates 230, 240, 260 and 270, and communicate with the second through hole 236. Thus, the negative pressure generated in the negative-pressure generating section 300 may be supplied to the second groove 237 via the second through hole 236, so that the solar panel 10 can be attached to the rotary plates 230, 240, 260 and 270. To more effectively apply the negative pressure between the solar panel 10 and each of the rotary plates 230, 240, 260 and 270, the second groove 237 may be widespread on each of the rotary plates 230, 240, 260 and 270.

The first rotary section 220 and the second rotary section 250 may be symmetrical to each other with respect to the stationary plate 210, and have the same structure.

The power transmitting section 500 may include a first transmission gear 510, a second transmission gear 520, a first transmission belt 530, a third transmission gear 540, a fourth transmission gear 550 and a second transmission belt 560.

The first transmission gear 510 may couple with the first driving shaft 440, and rotates interlocking with the first driving shaft 440. Therefore, the first transmission gear 510 rotates together with the first split gear 420 in the same direction as the first split gear 420.

The second transmission gear 520 may couple with the first driven shaft 521 and rotate together with the first driven shaft 521.

The first transmission belt 530 connects with the first transmission gear 510 and the second transmission gear 520, and transmits the rotary power from the first transmission gear 510 to the second transmission gear 520. Therefore, the second transmission gear 520 may rotate interlocking with the first transmission gear 510 in the same direction as the first transmission gear 510.

The third transmission gear 540 may couple with the second driving shaft 450, and rotate interlocking with the second driving shaft 450. Therefore, the third transmission gear 540 can rotate together with the second split gear 430 in the same direction as the second split gear 430.

The fourth transmission gear 550 may couple with the second driven shaft 551, and rotate together with the second driven shaft 551.

The second transmission belt 560 may connect with the third transmission gear 540 and the fourth transmission gear 550, and transmit the rotary power from the third transmission gear 540 to the fourth transmission gear 550. Therefore, the fourth transmission gear 550 may rotate interlocking with the third transmission gear 540 in the same direction as the third transmission gear 540.

Further, the power transmitting section 500 may additionally include a first adjuster 570 and a second adjuster 580.

The first adjuster 570 may include a first block 571 and a first presser 572. The first block 571 may be provided in an upper portion of the first rotary plate 230, and the first presser 572 may be provided in the first block 571 and press an upper portion of the first transmission belt 530. The first presser 572 may press the first transmission belt 530 to adjust the tension of the first transmission belt 530.

The second adjuster 580 may include a second block 581 and a second presser 582. The second block 581 may be provided in an upper portion of the third rotary plate 260, and the second presser 582 may be provided in the second block 581 and press an upper portion of the second transmission belt 560. The second presser 582 may press the second transmission belt 560 to adjust the tension of the second transmission belt 560.

Below, operations of the apparatus for cutting the solar panel will be described.

As shown in (a) of FIG. 10, in the state that the stationary plate 210 and the respective rotary plates 230, 240, 260 and 270 are arranged in a horizontal direction, the original solar panel 10 is put on throughout the stationary plate 210 and the respective rotary plates 230, 240, 260 and 270. At this time, a bottom surface of the original solar panel 10 may be formed with the cutting lines 20 at intervals corresponding to the widths of the stationary plate 210 and the respective rotary plates 230, 240, 260 and 270.

Then, the negative-pressure generating section 300 generates the negative pressure, so that the negative pressure can be induced between the bottom surface of the original solar panel 10 and the top surfaces of the stationary plate 210 and the respective rotary plates 230, 240, 260 and 270, thereby holding the original solar panel 10 on the stationary plate 210 and the respective rotary plates 230, 240, 260 and 270.

Then, as shown in (b) of FIG. 10, the main gear 410 rotates in a clockwise direction, and the first split gear 420 interworking the main gear 410 rotates in a counterclockwise direction, thereby rotating the second split gear 430 in the clockwise direction. At this time, the first split gear 420 and the second split gear 430 may rotate simultaneously at the same speed.

If the first split gear 420 rotates in the counterclockwise direction, the first transmission gear 510 interlocking with the first split gear 420 rotates in the counterclockwise direction, and the second transmission gear 520 is also rotated in the counterclockwise direction through the first transmission belt 530. Thus, in the state that the stationary plate 210 is stationary, the first rotary plate 230 can rotate in the counterclockwise direction with respect to the stationary plate 210, and the second rotary plate 240 can rotate in the counterclockwise direction with respect to the first rotary plate 230. That is, the first rotary plate 230 and the second rotary plate 240 may be rolled upward. The rotated angle of the first rotary plate 230 with respect to the stationary plate 210 may be equal to the rotated angle of the second rotary plate 240 with respect to the first rotary plate 230.

If the second split gear 430 rotates in the clockwise direction, the third transmission gear 540 interlocking with the second split gear 430 rotates in the clockwise direction, and the fourth transmission gear 550 is also rotated in the clockwise direction through the second transmission belt 560. Thus, in the state that the stationary plate 210 is stationary, the third rotary plate 260 can rotate in the clockwise direction with respect to the stationary plate 210, and the fourth rotary plate 270 can rotate in the clockwise direction with respect to the third rotary plate 260. That is, the third rotary plate 260 and the fourth rotary plate 270 may be rolled upward. The rotated angle of the third rotary plate 260 with respect to the stationary plate 210 may be equal to the rotated angle of the fourth rotary plate 270 with respect to the third rotary plate 260.

Since the first split gear 420 and the second split gear 430 rotate simultaneously at the same speed, the first rotary section 220 and the second rotary section 250 are rotated symmetrically to each other with respect to the stationary plate 210. As the first rotary section 220 and the second rotary section 250 are rolled upward, the original solar panel 10 attached to the stationary plate 210 and the respective rotary plates 230, 240, 260 and 270 is bent and cut at the cutting lines 20 into a plurality of small solar panels 11.

After completely cutting the original solar panel 10, the main gear 410 rotates in the clockwise direction, and the first rotary section 220 and the second rotary section 250 are rotated again and returned to an initial state, that is, in the horizontal direction parallel with the stationary plate 210. Further, the negative-pressure generating section 300 stops generating the negative pressure so that the cut solar panels 11 can be separated from the base section 200.

According to an embodiment of the present invention, the first rotary section and the second rotary section are simultaneously rolled upward symmetrically to each other with respect to the stationary plate, and therefore the original solar panel attached to the stationary plate and the respective rotary plates is cut into solar panels having a predetermined size. Thus, it is possible to massively get the plurality of small solar panels from the original solar panel at a time, thereby improving productivity.

Although a few exemplary embodiments of the present invention have been shown and described, it will be appreciated by those skilled in the art that changes may be made in these embodiments without departing from the principles and spirit of the invention, the scope of which is defined in the appended claims and their equivalents.

What is claimed is:

1. An apparatus for cutting a solar panel, comprising:
a power generating section which generates power;
a base section provided which is placed under the solar panel, the base section comprises a stationary plate, a first rotary section comprising a plurality of rotary plates rotatably coupled to one side of the stationary plate, and a second rotary section comprising a plurality of rotary plates rotatably coupled to the other side of the stationary plate;
a negative-pressure generating section which is placed under the stationary plate and the respective rotary plates, and generates negative pressure in between the solar panel and top surfaces of the stationary plate and the plurality of rotary plates so that the solar panel can be attached to the stationary plate and the plurality of rotary plates;
a power splitting section which receives the power from the power generating section and splits the power into rotary power in different directions; and
a power transmitting section which divisionally transmits the rotary power in different directions to the first rotary section and the second rotary section so that the solar panel can be bent and cut as the respective rotary plates are symmetrically rolled upward with respect to the stationary plate.

2. The apparatus for cutting the solar panel according to claim 1, wherein the power splitting section comprises:
a main gear which is rotated by the power provided from the power generating section;
a first split gear which comprises a first driving shaft at a center thereof, engages with the main gear and rotates in a counter direction to a rotating direction of the main gear;
a second split gear which comprises a second driving shaft at a center thereof, is shaped corresponding to the first split gear to engage with the first split gear and rotates in a counter direction to a rotating direction of the first split gear.

3. The apparatus for cutting the solar panel according to claim 2, wherein the stationary plate comprises a pair of first hinges at opposite respective end portions,
the pair of first hinges formed at one end portion of the stationary plate rotatably couples with the first driving shaft and the second driving shaft
the pair of first hinges formed at the other end portion of the stationary plate couples with a first locking shaft and a second locking shaft coupled to a mount.

4. The apparatus for cutting the solar panel according to claim 3, wherein the first rotary section comprises:
a first rotary plate which comprises a second hinge at one side and a third hinge at the other side, and rotatably couples with one side of the stationary plate as the second hinge axially couples with the first hinge formed at one side of the stationary plate by the first driving shaft and the first locking shaft; and
a second rotary plate which comprises a fourth hinge at one side and rotatably couples with the other side of the first rotary plate as the fourth hinge axially couples with the third hinge by the first driven shaft.

5. The apparatus for cutting the solar panel according to claim 4, wherein the second rotary section comprises:
a third rotary plate which comprises a fifth hinge at one side and a sixth hinge at the other side, and rotatably couples with the one side of the stationary plate as the fifth hinge axially couples with the first hinge formed at the other side of the stationary plate by the second driving shaft and the second locking shaft; and
a fourth rotary plate which comprises a seventh hinge at one side and rotatably couples with the other side of the third rotary plate as the seventh hinge axially couples with the sixth hinge by the second driven shaft.

6. The apparatus for cutting the solar panel according to claim 5, wherein the first driving shaft and the second driving shaft respectively couple with the corresponding first hinges by bearings to be rotatable independently, and
the first driving shaft and the second driving shaft respectively comprise a first stepped portion and a second stepped portion which are flat on outer circumferential surfaces thereof, and the second hinge and the fifth hinge respectively comprise a first coupling groove and a second coupling groove on inner circumferential surfaces thereof shaped corresponding to and coupling with the first stepped portion and the second stepped portion to transmit rotary power of the first driving shaft and the second driving shaft.

7. The apparatus for cutting the solar panel according to claim 5, wherein the first driven shaft couples with the third hinge by a bearing to be rotatable independently, and comprises a third stepped portion to be pressed by a first locking pin coupling with a first locking hole formed in the fourth hinge so that the second rotary plate can rotate together with the first driven shaft.

8. The apparatus for cutting the solar panel according to claim 5, wherein the second driven shaft couples with the sixth hinge by a bearing to be rotatable independently, and comprises a fourth stepped portion to be pressed by a second locking pin coupling with a second locking hole formed in the seventh hinge so that the fourth rotary plate can rotate together with the second driven shaft.

9. The apparatus for cutting the solar panel according to claim 5, wherein the power transmitting section comprises:
a first transmission gear which couples with the first driving shaft and rotates together with the first split gear in the same direction as the first split gear rotates;
a second transmission gear which couples with the first driven shaft and rotates together with the first driven shaft;
a first transmission belt which connects with the first transmission gear and the second transmission gear and transmits rotary power from the first transmission gear to the second transmission gear;
a third transmission gear which couples with the second driving shaft and rotates together with the second split gear in the same direction as the second split gear rotates;
a fourth transmission gear which couples with the second driven shaft and rotates together with the second driven shaft; and
a second transmission belt which connects with the third transmission gear and the fourth transmission gear and transmits rotary power from the third transmission gear to the fourth transmission gear.

10. The apparatus for cutting the solar panel according to claim 9, wherein the power transmitting section further comprises:
a first adjuster which is provided in an upper portion of the first rotary plate, and presses the first transmission belt to adjust tension of the first transmission belt, and
a second adjuster which is provided in an upper portion of the third rotary plate and presses the second transmission belt to adjust tension of the second transmission belt.

11. The apparatus for cutting the solar panel according to claim 9, wherein
the stationary plate comprises first settling grooves at the opposite end portions on a top surface thereof in a widthwise direction of the stationary plate,
the first rotary plate comprises second settling grooves at the opposite end portions on a top surface thereof in a widthwise direction of the first rotary plate,
the third rotary plate comprises third settling grooves at the opposite end portions on a top surface thereof in a widthwise direction of the third rotary plate, the first driving shaft is provided with a first elastic member for elastically urging the first rotary plate to rotate in a spreading-out direction with respect to the stationary plate, and
the second driving shaft is provided with a second elastic member for elastically urging the third rotary plate to rotate in a spreading-out direction with respect to the stationary plate.

12. The apparatus for cutting the solar panel according to claim 1, wherein
the stationary plate comprises a first through hole formed to penetrate the stationary plate in a thickness direction and communicate with the negative-pressure generating section placed under the stationary plate, and a first groove formed on the a top surface of the stationary plate and communicating with the first through hole, and
the rotary plate comprises a second through hole formed to penetrate the rotary plate in a thickness direction and communicate with the negative-pressure generating section placed under each rotary plate, and a second groove formed on a top surface of the rotary plate and communicating with the second through hole.
